(19) United States
(12) Patent Application Publication
(10) Pub. No.: US 2026/0027756 A1
(43) Pub. Date: Jan. 29, 2026

(54) Method and System for Shaping Partial Fields

(71) Applicant: CANON KABUSHIKI KAISHA, Tokyo (JP)

(72) Inventors: Daniel Ironside, Austin, TX (US); Logan L. Simpson, Coupland, TX (US)

(21) Appl. No.: 18/787,345

(22) Filed: Jul. 29, 2024

(51) Int. Cl. B29C 43/58; B29C 43/02; B29C 43/36; G03F 7/00

(52) U.S. Cl. CPC B29C 43/58; B29C 43/02; B29C 43/36; G03F 7/0002; B29C 2043/5808; B29C 2043/5833

(57) ABSTRACT

An imprinting method includes moving a template having a shaping surface towards a substrate based on position information, upon reaching a first distance from the substrate, switching from moving the template based on position information to moving based on force information, contacting the shaping surface with formable material such that the total surface area of the shaping surface overlaps the substrate, moving the template towards the substrate based on position information, upon reaching a second distance from the substrate, switching from moving the template based on position information to moving based on force information, contacting, with the shaping surface, the formable material, wherein the shaping surface overlaps an edge of the substrate. The second distance is equal to the first distance adjusted based on at least one control parameter associated with contacting the formable material with the shaping surface when the shaping surface overlaps the edge of the substrate.

### BACKGROUND

### Technical Field

The present disclosure relates to photomechanical shaping systems (e.g., Nanoimprint Lithography and Inkjet Adaptive Planarization). In particular, the present disclosure relates to methods of imprinting (also referred to as shaping) full fields, partial fields, and small partial fields on a substrate.

### Description of the Related Art

Nano-fabrication includes the fabrication of very small structures that have features on the order of 100 nanometers or smaller. One application in which nano-fabrication has had a sizeable impact is in the fabrication of integrated circuits. The semiconductor processing industry continues to strive for larger production yields while increasing the circuits per unit area formed on a substrate. Improvements in nano-fabrication include providing greater process control and/or improving throughput while also allowing continued reduction of the minimum feature dimensions of the structures formed.

One nano-fabrication technique in use today is commonly referred to as nanoimprint lithography. Nanoimprint lithography is useful in a variety of applications including, for example, fabricating one or more layers of integrated devices by shaping a film on a substrate. Examples of an integrated device include but are not limited to CMOS logic, microprocessors, NAND Flash memory, NOR Flash memory, DRAM memory, MRAM, 3D cross-point memory, Re-RAM, Fe-RAM, STT-RAM, MEMS, and the like. Exemplary nanoimprint lithography systems and processes are described in detail in numerous publications, such as U.S. Pat. Nos. 8,349,241, 8,066,930, and 6,936,194, all of which are hereby incorporated by reference herein.

The nanoimprint lithography technique disclosed in each of the aforementioned patents describes the shaping of a film on a substrate by the formation of a relief pattern in a formable material (polymerizable) layer. The shape of this film may then be used to transfer a pattern corresponding to the relief pattern into and/or onto an underlying substrate.

The shaping process uses a template spaced apart from the substrate. The formable material is applied onto the substrate. The template is brought into contact with the formable material that may have been deposited as a drop pattern using the formable material to spread and fill the space between the template and the substrate. The template may be used to imprint full fields and/or partial fields on the substate. The formable material is solidified to form a film that has a shape (pattern) conforming to a shaping surface of the template. After solidification, the template is separated from the solidified layer such that the template and the substrate are spaced apart.

The substrate and the solidified layer may then be subjected to known steps and processes for device (article) fabrication, including, for example, curing, oxidation, layer formation, deposition, doping, planarization, etching, formable material removal, dicing, bonding, and packaging, and the like. For example, the pattern on the solidified layer may be subjected to an etching process that transfers the pattern into the substrate.

When imprinting full fields, it is advantageous to switch from position control to force control at a predetermined distance from the substrate in order to obtain good filling performance. The same is true for imprinting small fields and small partial fields. However, while all full fields are the same and have the same predetermined distance for switching control, each unique partial field and small partial field should have a distinct predetermined distance for switching the control for good filling performance. Determining the predetermined distance for each unique partial field and small partial field through experimentation is burdensome. Accordingly, there is a need in the art for a method of imprinting partial fields and small partial fields in which determining the location for switching the control does not require burdensome experimentation.

### SUMMARY

An imprinting method includes moving a template having a shaping surface towards a substrate based on first predetermined position information, upon reaching a first predetermined distance from the substrate, switching from moving the template based on the first predetermined position information to moving the template based on first predetermined force information, contacting the shaping surface with formable material on the substrate such that the total surface area of the shaping surface overlaps the substrate, moving the template towards a substrate based on second predetermined position information, upon reaching a second predetermined distance from the substrate, switching from moving the template based on the second predetermined position information to moving the template based on second predetermined force information, contacting, with the shaping surface, the formable material on the substrate, wherein the shaping surface overlaps an edge of the substrate, wherein the second predetermined distance is equal to the first predetermined distance that is adjusted based on at least one control parameter associated with contacting the formable material with the shaping surface when the shaping surface overlaps the edge of the substrate.

An imprinting method includes moving a template with a shaping surface towards a substrate based on predetermined position information, upon reaching a predetermined distance from the substrate, switching from moving the template based on the predetermined position information to moving the template based on predetermined force information, contacting, with the shaping surface, formable material on the substrate, wherein the shaping surface overlaps an edge of the substrate, wherein the predetermined distance is equal to a reference distance from the substrate that is adjusted based on at least one control parameter associated with contacting the shaping surface with the partial overlap amount, and wherein the reference distance is a distance from the substrate where, in a reference imprinting in which the total surface area of the shaping surface overlaps the substrate, movement of the template switches from being moved based on reference position information to being moved based on reference force information.

A imprinting system includes one or more memory, and one or more processors configured to: move a template having a shaping surface towards a substrate based on first predetermined position information, upon reaching a first predetermined distance from the substrate, switch from moving the template based on the first predetermined position information to moving the template based on first predetermined force information, move the shaping surface with formable material on the substrate such that the total surface area of the shaping surface overlaps the substrate, move the template towards a substrate based on second predetermined position information, upon reaching a second predetermined distance from the substrate, switch from moving the template based on the second predetermined position information to moving the template based on second predetermined force information, contact, with the shaping surface, the formable material on the substrate, wherein the shaping surface overlaps an edge of the substrate, wherein the second predetermined distance is equal to the first predetermined distance that is adjusted based on at least one control parameter associated with contacting the formable material with the shaping surface when the shaping surface overlaps the edge of the substrate.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF THE FIGURES

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure and are therefore not to be considered limiting of its scope, for the invention may admit to other equally effective embodiments.

FIG. 1 is an illustration of an exemplary nanoimprint lithography system having a template with a mesa spaced apart from a substrate as used in an embodiment.

FIGS. 2A-B are illustrations of exemplary templates that may be used in an embodiment.

FIG. 3 is a flowchart illustrating an exemplary imprinting method as used in an embodiment.

FIGS. 4A-B are illustrations of layouts of fields on substrates as used in an embodiment.

FIGS. 4C-D are illustrations of a small partial field on substrate as used in an embodiment.

FIGS. 5A-F are illustrations of a small partial field on substrate and template as used in an embodiment.

FIG. 6A is a flowchart illustrating a method of position control of a template chuck.

FIG. 6B is a flowchart illustrating a method of force control of a template chuck.

FIG. 7A is an illustration of a template chuck and substrate for imprinting a full field using a target imprint plane.

FIG. 7B is an illustration of a template chuck and substrate for imprinting a partial field using a target imprint plane.

FIG. 8 is a flowchart illustrating additional details of the flowchart of FIG. 3.

FIGS. 9A-9G show timing charts for performing the imprinting method of FIG. 3.

FIG. 10 is a flowchart showing illustrating additional details of the flowchart of FIG. 3.

Throughout the figures, the same reference numerals and characters, unless otherwise stated, are used to denote like features, elements, components, or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

The nanoimprint lithography technique can be used in a step and repeat manner to shape a film with a template in a plurality of fields across a substrate. The substrate and a patterning area/shaping surface (mesa) of a template may have different shapes and sizes. For example, the substrate may have a region to be patterned that is circular, elliptical, polygonal, or some other shape. While the mesa is typically smaller than the substrate and has a different shape than the substrate. The substrate is divided into a plurality of full fields and a plurality of partial fields. The full fields are the same size as the mesa. That is the entire surface area of the mesa is equal to the area of a full field. In other words, for a full field, the total surface area of the shaping surface overlaps the substrate. The partial fields are those fields on the edge of the substrate in which the edge of the region to be patterned on the substrate intersects with the patterning area of the mesa. These fields may be divided into multiple categories based on their shape and/or area relative to the full field. For a partial field, only a portion of the surface area of the mesa is equal to the area of the area of a partial field. In other words, for a partial field, the shaping surface overlaps an edge of the substrate.

The partial fields having an area that is less than the an area of a full field area (e.g., the partial field area may be 5% to 99% of the full field area or 10% to 95% of the full field area) tend to have higher defectivity and/or higher processing time than full fields. In addition, small partial fields which may have an area of 50% or less of a full field area or 35% or less than a full field area, are particularly challenging. That is, a small partial field has an area that is equal to 50% or less (or 35% or less) of the area of a full field, which is 50% or less (or 35% or less) of the entire surface area of the mesa. It is desirable to lower defectivity and/or higher processing time for partial fields and small partial fields. The applicant has found that the defectivity and/or higher processing time for small partial fields can be reduced if the initial contact point (ICP) is well chosen. One method of choosing the ICP was described in U.S. Pat. No. 11,614,693.

However, even when a target ICP is well chosen, the applicant has found that, during the imprinting process, it is advantageous to switch from position control to force control at a predetermined distance from the substrate in order to obtain good filling performance. The predetermined distance can be determined through experimentation. However, determining the predetermined distance for each unique partial field and small partial field through experimentation is burdensome. Disclosed herein is a method of imprinting partial fields and small partial fields in which the predetermined distance for switching the control is determined without burdensome experimentation.

### Shaping System

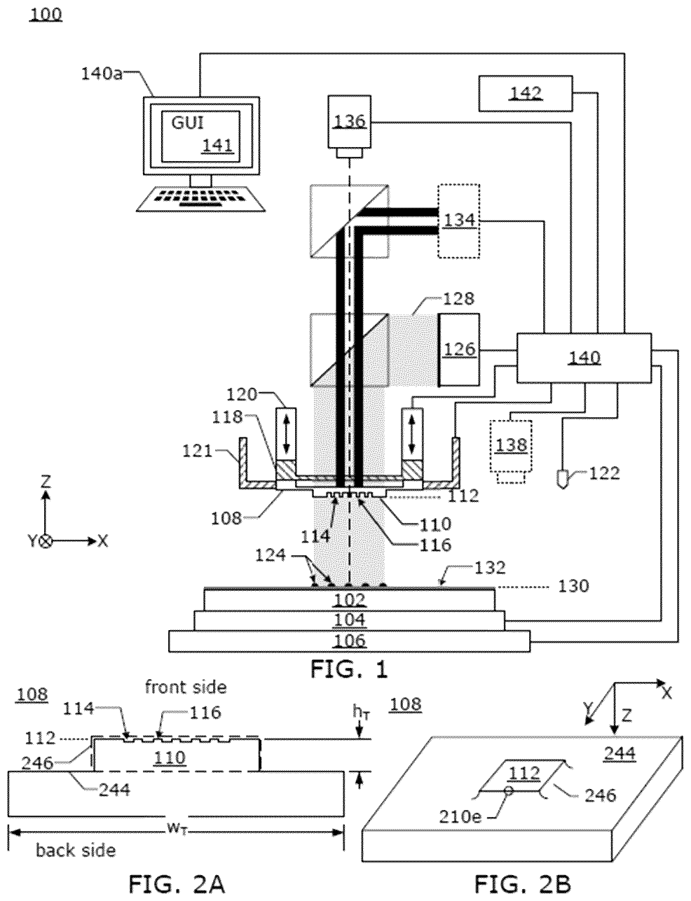

FIG. 1 is an illustration of a shaping system 100 (for example a nanoimprint lithography system or inkjet adaptive planarization system) in which an embodiment may be implemented. The shaping system 100 is used to produce an imprinted (shaped) film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the positional axes x, y, and z, and rotational axes θ, ψ, and φ. The substrate positioning stage 106, the substrate 102, and the substrate chuck 104 may also be positioned on a base (not shown). The substrate positioning stage may be a part of a positioning system. In an alternative embodiment, the substrate chuck 104 may be attached to the base.

Spaced-apart from the substrate 102 is a template 108 (also referred to as a superstrate). The template 108 may include a body having a mesa (also referred to as a mold) 110 extending towards the substrate 102 on a front side of the template 108. The mesa 110 may have a shaping surface 112 thereon also on the front side of the template 108. The shaping surface 112, also known as a patterning surface, is the surface of the template that shapes the formable material 124. The mesa, and more particularly, the shaping surface 112, has a surface area facing the substrate 102. In an embodiment, the shaping surface 112 is planar and is used to planarize the formable material. Alternatively, the template 108 may be formed without the mesa 110, in which case the surface of the template facing the substrate 102 is equivalent to the mesa 110 and the shaping surface 112 is that surface of the template 108 facing the substrate 102.

The template 108 may be formed from such materials including, but not limited to, fused-silica, quartz, silicon, organic polymers, siloxane polymers, borosilicate glass, fluorocarbon polymers, metal, hardened sapphire, and/or the like. The shaping surface 112 may have features defined by a plurality of spaced-apart template recesses 114 and/or template protrusions 116. The shaping surface 112 defines a pattern that forms the basis of a pattern to be formed on the substrate 102. In an alternative embodiment, the shaping surface 112 is featureless in which case a planar surface is formed on the substrate. In an alternative embodiment, the shaping surface 112 is featureless and the same size as the substrate and a planar surface is formed across the entire substrate.

The template 108 may be coupled to a template chuck 118. The template chuck 118 may be, but is not limited to, vacuum chuck, pin-type chuck, groove-type chuck, electrostatic chuck, electromagnetic chuck, and/or other similar chuck types. The template chuck 118 may be configured to apply stress, pressure, and/or strain to template 108 that varies across the template 108. The template chuck 118 may include a template magnification control system 121. The template magnification control system 121 may include piezoelectric actuators (or other actuators) which can squeeze and/or stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to a shaping head 120 which is a part of the positioning system. The shaping head 120 may be moveably coupled to a bridge. The shaping head 120 may include one or more actuators such as voice coil motors, piezoelectric motors, linear motor, nut and screw motor, etc., which are configured to move the template chuck 118 relative to the substrate in at least the z-axis direction, and potentially other directions (e.g., positional axes x, and y, and rotational axes θ, ψ, and φ).

The shaping system 100 may further comprise a fluid dispenser 122. The fluid dispenser 122 may also be moveably coupled to the bridge. In an embodiment, the fluid dispenser 122 and the shaping head 120 share one or more or all of the positioning components. In an alternative embodiment, the fluid dispenser 122 and the shaping head 120 move independently from each other. The fluid dispenser 122 may be used to deposit liquid formable material 124 (e.g., polymerizable material) onto the substrate 102 in a drop pattern. Additional formable material 124 may also be added to the substrate 102 using techniques, such as, drop dispense, spin-coating, dip coating, chemical vapor deposition (CVD), physical vapor deposition (PVD), thin film deposition, thick film deposition, and/or the like prior to the formable material 124 being deposited onto the substrate 102. The formable material 124 may be dispensed upon the substrate 102 before and/or after a desired volume is defined between the shaping surface 112 and the substrate 102 depending on design considerations. The formable material 124 may comprise a mixture including a monomer as described in U.S. Pat. Nos. 7,157,036 and 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that induces a phase change in the liquid formable material into a solid material whose top surface is determined by the shape of the shaping surface 112. The curing system may include at least a radiation source 126 that directs actinic energy along an exposure path 128. The shaping head and the substrate positioning stage 106 may be configured to position the template 108 and the substrate 102 in superimposition with the exposure path 128. The radiation source 126 sends the actinic energy along the exposure path 128 after the template 108 has contacted the formable material 124. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124. In an embodiment, the actinic energy may be directed through both the template chuck 118 and the template 108 into the formable material 124 under the template 108. In an embodiment, the actinic energy produced by the radiation source 126 is UV light that induces polymerization of monomers in the formable material 124.

The shaping system 100 may further comprise a field camera 136 that is positioned to view the spread of formable material 124 after the template 108 has contacted the formable material 124. FIG. 1 illustrates an optical axis of the field camera's imaging field as a dashed line. As illustrated in FIG. 1 the shaping system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. The optical axis of the field camera 136 as illustrated in FIG. 1 is straight but may be bent by one or more optical components. The field camera 136 may include one or more of: a CCD; a sensor array; a line camera; and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting (shaping) process. The field camera 136 may also be configured to measure interference fringes, which change as the formable material spreads 124 between the gap between the shaping surface 112 and the substrate surface 130.

The shaping system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as lenses, mirrors, optical diaphragms, apertures, filters, prisms, polarizers, windows, adaptive optics, and/or light sources. The droplet inspection system 138 may be positioned to inspect droplets prior to the shaping surface 112 contacting the formable material 124 on the substrate 102. In an alternative embodiment, the field camera 136 may be configured as a droplet inspection system 138 and used prior to the shaping surface 112 contacting the formable material 124.

The shaping system 100 may further include a thermal radiation source 134 which may be configured to provide a spatial distribution of thermal radiation to one or both of the template 108 and the substrate 102. The thermal radiation source 134 may include one or more sources of thermal electromagnetic radiation that will heat up one or both of the substrate 102 and the template 108 and does not cause the formable material 124 to solidify. The thermal radiation source 134 may include a SLM such as a digital micromirror device (DMD), Liquid Crystal on Silicon (LCoS), Liquid Crystal Device (LCD), etc., to modulate the spatio-temporal distribution of thermal radiation. The shaping system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation source 134 may send the thermal radiation along a thermal radiation path (which in FIG. 1 is illustrated as 2 thick dark lines) after the template 108 has contacted the formable material 124. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation source 134 is underneath the substrate 102, and thermal radiation path is not combined with the actinic radiation and the visible light.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, drop dispense, slot dispense, etc. In an embodiment, the substrate 102 may be a semiconductor wafer, a glass wafer, a sapphire wafer, or some other material. In another embodiment, the substrate 102 may be a blank template (replica blank) that may be used to create a daughter template after being imprinted.

The shaping system 100 may include an imprint field atmosphere control system such as gas and/or vacuum system, an example of which is described in U.S. Patent Publication No. 2010/0096764 and U.S. Pat. No. 10,895,806 which are hereby incorporated by reference. The gas and/or vacuum system may include one or more of pumps, valves, solenoids, gas sources, gas tubing, etc. which are configured to cause one or more different gases to flow at different times and different regions. The gas and/or vacuum system may be connected to a first gas transport system that transports gas to and from the edge of the substrate 102 and controls the imprint field atmosphere by controlling the flow of gas at the edge of the substrate 102. The gas and/or vacuum system may be connected to a second gas transport system that transports gas to and from the edge of the template 108 and controls the imprint field atmosphere by controlling the flow of gas at the edge of the template 108. The gas and/or vacuum system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The shaping system 100 may be regulated, controlled, and/or directed by one or more processors 140 (controller) in communication with one or more components and/or subsystems such as the substrate chuck 104, the substrate positioning stage 106, the template chuck 118, the shaping head 120, the fluid dispenser 122, the radiation source 126, the thermal radiation source 134, the field camera 136, imprint field atmosphere control system, and/or the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The controller 140 may include a plurality of processors that are both included in the shaping system 100a and in communication with the shaping system 100a. The processor 140 may be in communication with a networked computer 140a on which analysis is performed and control files such as a drop pattern are generated. In an embodiment, there are one or more graphical user interface (GUI) 141 on one or both of the networked computer 140a and a display in communication with the processor 140 which are presented to an operator and/or user.

Either the shaping head 120, the substrate positioning stage 106, or both varies a distance between the mold 110 and the substrate 102 to define a desired space (a bounded physical extent in three dimensions) that is filled with the formable material 124. For example, the shaping head 120 may apply a force to the template 108 such that mold 110 is in contact with the formable material 124. After the desired volume is filled with the formable material 124, the radiation source 126 produces actinic radiation (e.g., UV, 248 nm, 280 nm, 350 nm, 365 nm, 395 nm, 400 nm, 405 nm, 435 nm, etc.) causing formable material 124 to cure, solidify, and/or cross-link; conforming to a shape of the substrate surface 130 and the shaping surface 112, defining a patterned layer on the substrate 102. The formable material 124 is cured while the template 108 is in contact with formable material 124, forming the patterned layer on the substrate 102. Thus, the shaping system 100 uses a shaping process to form the patterned layer which has recesses and protrusions which are an inverse of the pattern in the shaping surface 112. In an alternative embodiment, the shaping system 100 uses a shaping process to form a planar layer with a featureless shaping surface 112.

The shaping process may be done repeatedly in a plurality of imprint fields (also known as just fields or shots) that are spread across the substrate surface 130. Each of the full field imprint fields may be the same size as the mesa 110 or just the pattern area of the mesa 110. The pattern area of the mesa 110 is a region of the shaping surface 112 which is used to imprint (shape) patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field (shaping field) which is the same size as the substrate 102 or the area of the substrate 102 which is to be patterned with the mesa 110. In an alternative embodiment, the imprint fields overlap. As noted above, some of the imprint fields may be partial imprint fields or small partial imprint fields which intersect with a boundary of the substrate 102.

The patterned layer may be formed such that it has a residual layer having a residual layer thickness (RLT) that is a minimum thickness of formable material 124 between the substrate surface 130 and the shaping surface 112 in each imprint field. The patterned layer may also include one or more features such as protrusions which extend above the residual layer having a thickness. These protrusions match the recesses 114 in the mesa 110.

### Template

FIG. 2A is an illustration of a template 108 (not to scale) that may be used in an embodiment. The shaping surface 112 may be on a mesa 110 (identified by the dashed box in FIG. 2A). The mesa 110 is surrounded by a recessed surface 244 on the front side of the template. The mesa 110 has a mesa height hr. The mesa height hr may between 1-200 μm. Mesa sidewalls 246 connect the recessed surface 244 to shaping surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles. FIG. 2B is a perspective view of the template 108 (not to scale) showing the mesa edges 210e. FIG. 2B illustrates that the intersection of the mesa sidewalls 246 and the recessed surface 244 may have some curvature due to the process of etching away material form a template precursor to form the mesa 110 on the template 108. The template 108 may have a square planar shape with a template width WT as illustrated in FIGS. 2A-B. In an alternative embodiment, the template width WT is a characteristic width and a planar shape of the template 108 may be a rectangle, parallelogram, polygon, or circle, or some other shape. The template width WT may be between 10-450 mm.

### Shaping Process

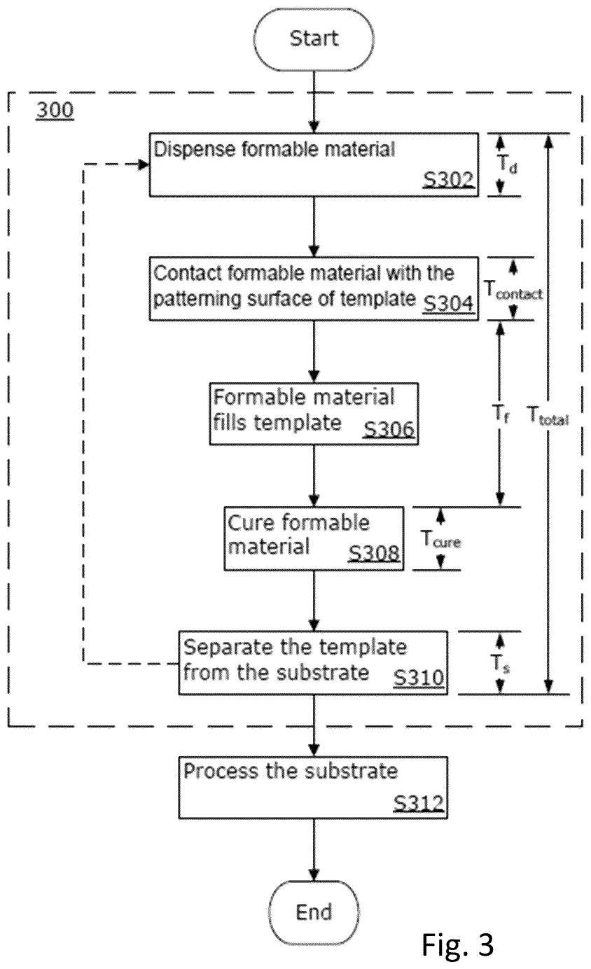

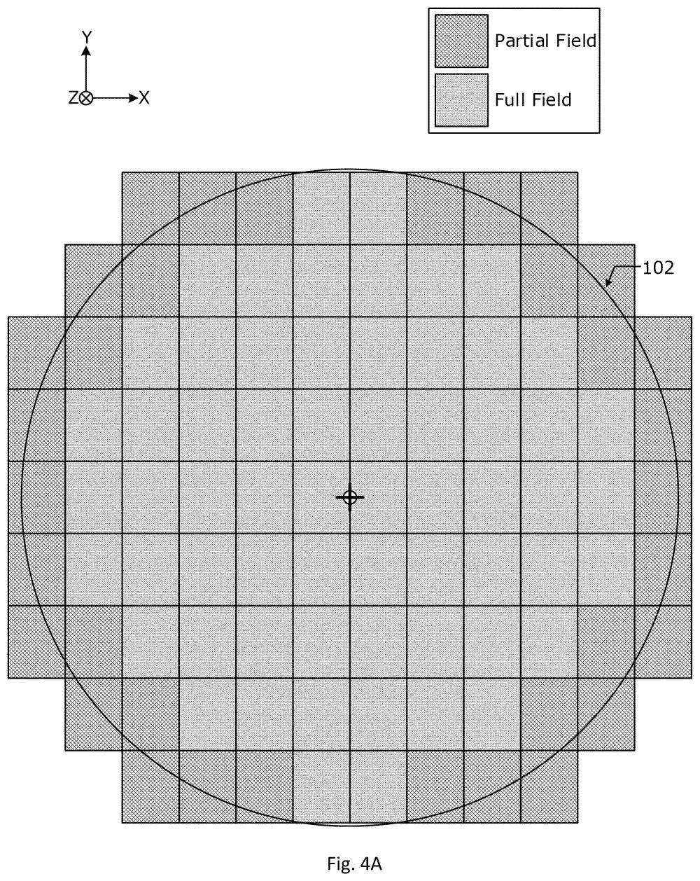

FIG. 3 is a flowchart of a method of manufacturing an article (device) that includes a shaping process 300 performed by the shaping system 100. The shaping process 300 can be used to form patterns in formable material 124 on one or more imprint fields (also referred to as: pattern areas or shot areas). The shaping process 300 may be performed repeatedly on a plurality of substrates 102 by the shaping system 100. The processor 140 may be used to control the shaping process 300.

In an alternative embodiment, the shaping process 300 is used to planarize the substrate 102. In which case, the shaping surface 112 is featureless and may also be the same size or larger than the substrate 102.

The beginning of the shaping process 300 may include a template mounting step causing a template conveyance mechanism to mount a template 108 onto the template chuck 118. The shaping process 300 may also include a substrate mounting step, the processor 140 may cause a substrate conveyance mechanism to mount the substrate 102 onto the substrate chuck 104. The substrate may have one or more coatings and/or structures. The order in which the template 108 and the substrate 102 are mounted onto the shaping system 100 is not particularly limited, and the template 108 and the substrate 102 may be mounted sequentially or simultaneously.

In a positioning step, the processor 140 may cause one or both of the substrate positioning stage 106 and/or a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by a shaping field index i. In which N is the number of shaping fields and is a real positive integer such as 1, 10, 62, 75, 84, 100, etc. {N∈ [symbol] ⁺}. In a dispensing step S302, the processor 140 may cause the fluid dispenser 122 to dispense formable material based on a drop pattern onto an imprinting field. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field may be moved relative to the fluid dispenser 122 while the fluid dispenser is ejecting formable material 124. Thus, the time at which some of the droplets land on the substrate may vary across the imprint field i. The dispensing step S302 may be performed during a dispensing period T_{d} for each imprint field i.

In an embodiment, during the dispensing step S302, the formable material 124 is dispensed onto the substrate 102 in accordance with a drop pattern. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, then a contacting step S304 may be initiated, the processor 140 may cause one or both of the substrate positioning stage 106 and a template positioning stage to bring the shaping surface 112 of the template 108 into contact with the formable material 124 in a particular imprint field. The contacting step S304 may be performed during a contacting period T_{contact} which starts after the dispensing period T_{d} and begins with the initial contact of the shaping surface 112 with the formable material 124. As discussed in more detail below, prior to the contact period, control of the movement of the template chuck may switch from a position control method to force control method. In an embodiment, by the beginning of the contact period T_{contact} the template chuck 118 is configured to bow out the template 108 so that only a portion of the shaping surface 112 is in contact with a portion of the formable material. In an embodiment, the contact period T_{contact} ends when the template 108 is no longer bowed out by the template chuck 118. The degree to which the shaping surface 112 is bowed out relative to the substrate surface 130 may be estimated with the spread camera 136. The spread camera 136 may be configured to record interference fringes due to reflectance from at least the shaping surface 112 and the substrate surface 130. The greater the distance between neighboring interference fringes, the larger the degree to which the shaping surface 112 is bowed out.

During a filling step S306, the formable material 124 spreads out towards the edge of the imprint field and the mesa sidewalls 246. The edge of the imprint field may be defined by the mesa sidewalls 246. How the formable material 124 spreads and fills the mesa may be observed via the field camera 136 and may be used to track a progress of a fluid front of formable material. In an embodiment, the filling step S306 occurs during a filling period T_{f}. The filling period T_{f} begins when the contacting step S304 ends. The filling period T_{f} ends with the start of a curing period T_{C}. In an embodiment, during the filling period T_{f} the back pressure and the force applied to the template are held substantially constant. Substantially constant in the present context means that the back pressure variation and the force variation is within the control tolerances of the shaping system 100 which may be less 0.1% of the set point values.

In a curing step S308, the processor 140 may send instructions to the radiation source 126 to send a curing illumination pattern of actinic radiation through the template 108, the mesa 110, and the shaping surface 112 during a curing period T_{C}. The curing illumination pattern provides enough energy to cure (polymerize) the formable material 124 under the shaping surface 112. The curing period T_{C} is a period in which the formable material under the template receives actinic radiation with an intensity that is high enough to solidify (cure) the formable material. In an alternative embodiment, the formable material 124 is exposed to a gelling illumination pattern of actinic radiation before the curing period T_{C} which does not cure the formable material but does increase the viscosity of the formable material.

In a separation step S310, the processor 140 uses one or more of: the substrate chuck 104; the substrate positioning stage 106, template chuck 118, and the shaping head 120 to separate the shaping surface 112 of the template 108 from the cured formable material on the substrate 102 during a separation period T_{S}. If there are additional imprint fields to be imprinted, then the process moves back to step S302. In an alternative embodiment, during step S302 two or more imprint fields receive formable material 124 and the process moves back to steps S302 or S304.

In an embodiment, after the shaping process 300 is finished additional semiconductor manufacturing processing is performed on the substrate 102 in a processing step S312 so as to create an article of manufacture (e.g., semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, mounting, circuit board assembly, and the like. The substrate 102 may be processed to produce a plurality of articles (devices).

### Layout of Fields on Substrate

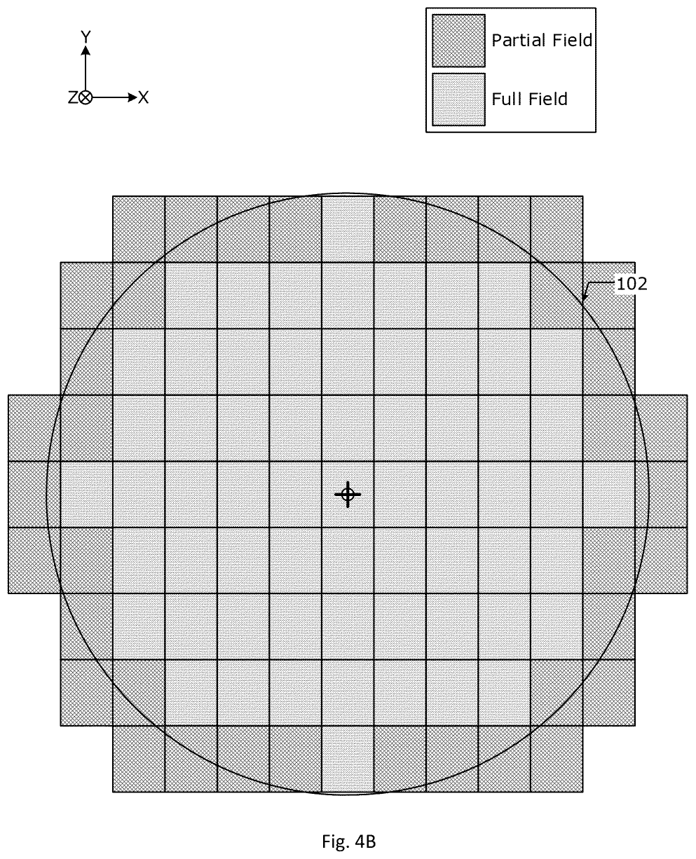

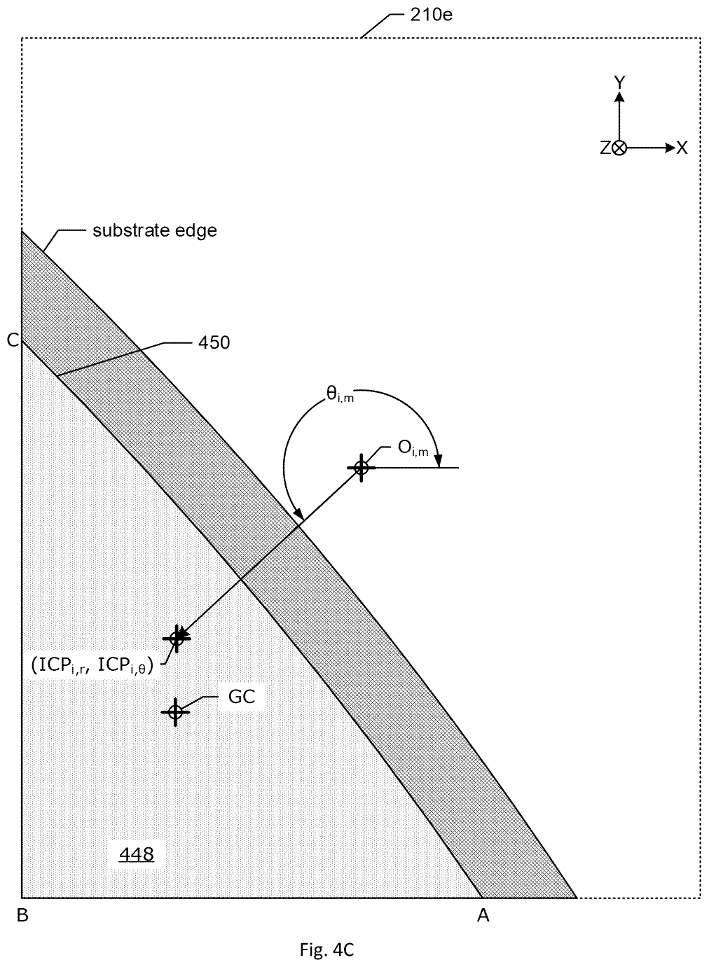

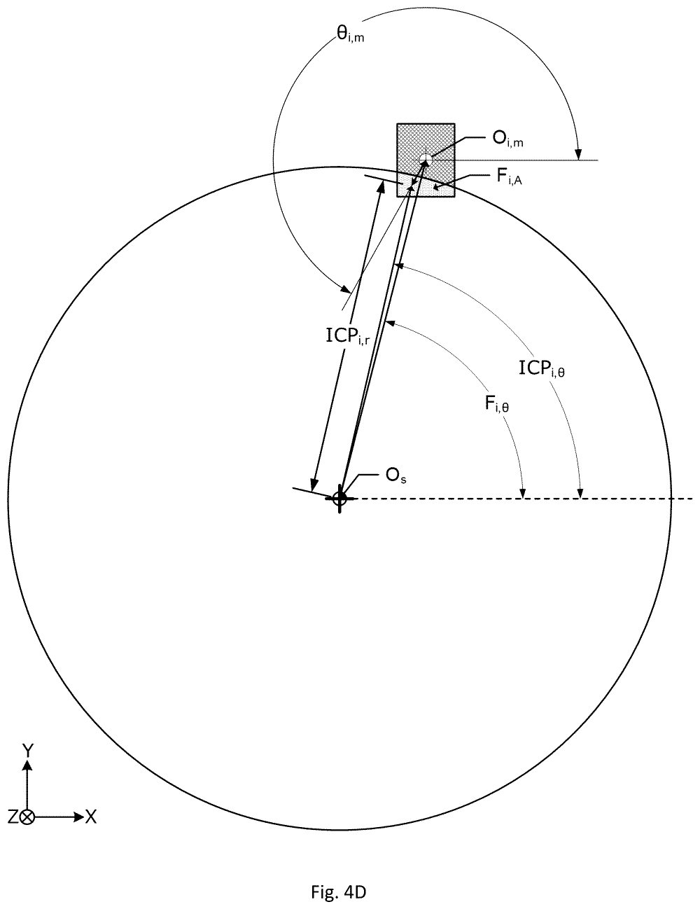

The shaping process 300 can be used in a step and repeat manner to shape a film with a template 108 in a plurality of fields across the substrate 102. The substrate 102 and a patterning area (mesa 110) of a template 108 may have different shapes and sizes. For example, the substrate 102 may have a region to be patterned that is circular, elliptical, polygonal, or some other shape. The mesa 110 is typically smaller than the substrate 102 and has a different shape then the substrate 102. The substrate 102 is divided into a plurality of full fields and a plurality of partial fields/small partial fields as illustrated in FIGS. 4A-B. As discussed above, the full fields are the same size as the mesa 110 or patterning area (shaping surface) of the mesa. That is, the entire surface area of the mesa 110 is equal to the area of one full field such that the total surface area of the shaping surface overlaps the substrate. The partial fields and small partial fields are those fields on the edge of the substrate in which the edge of the region to be patterned on the substrate intersects with the patterning area of the mesa (shaping surface), such that the shaping surface overlaps an edge of the substrate. As noted above, a partial field is a field whose area is less than the area of a full field, which is also less than the entire surface area (shaping surface) of the mesa 110. These fields may be divided into multiple categories based on their shape and/or area relative to the full field. A subset of those partial fields maybe categorized as small partial fields. A partial field may be defined as having a surface area that is less than an entire surface area of the mesa 110, may be defined as having a surface area that is 5% to 99% of the entire surface area of the mesa, or may be defined as having a surface area that is 10% to 95% of the entire surface area of the mesa. A small partial field may be defined as having a surface area that is equal to 50% or less (or 35% or less) of the area of a full field, which is also 50% or less (or 35% or less) of the entire surface area of the mesa 110.

### Small Partial Fields

FIG. 4C is an illustration of a particular small partial field 448 on a substrate 102 in the coordinate system of the mesa 110. In FIG. 4C the mesa edges 210e are illustrated as dotted lines. FIG. 4C also shows the mesa origin O_{i,m} of the coordinate system of the mesa which is at the center of the mesa 110. A patternable area edge 450 is shown inset from the substrate edge. In an embodiment, the patternable area edge 450 may be inset from the substrate edge by between 0 to 3 mm. The non-patterned area is illustrated with a diamond gird pattern in FIG. 4C. The width of the non-patterned area may be determined by an edge treatment of the substrate 102 which may have been treated to have rounded, beveled, or chamfered edges. The substrate 102 may also have undergone numerous previous processes which cause the edge to have a random unpredictable pattern. The substrate 102 may also have an orientation feature such as a notch or a flat edge.

As illustrated in FIG. 4C the extent of the particular small partial field 448 is defined on two sides by the mesa edge 210e which intersect at a vertex B. The extent of the small partial field 448 is also defined by the arc of the patternable area edge 450. The arc of the patternable area edge 450 may be defined as a portion of a circle, an ellipse, a spline, a polygon, or other geometric quantity that can be used to define a shape of the patternable area edge 450. The arc of the patternable area edge 450 intersects the mesa edges 210e at vertices A and C. This is an exemplary small partial field. The small partial field may have other shapes, which have at least on curved edge and 1 or more straight edges.

### Initial Contact Point

The shaping process 300 is controlled using numerous parameters. In an embodiment, one of the process parameters used during the contacting step S302 is the target initial contact point (ICP) for each field i (ICPᵢ={ICP_{i,θ}, ICP_{i,r}}). In an embodiment, polar coordinates relative to the substrate center (Oₛ) may be used to describe target ICP. The location of the target ICPᵢ may also be described as angle θ_{i,m} relative to center of the mesa O_{i,m}. In an alternative embodiment, another coordinate system may be used. The target ICP is the point in the field in which the template 108 is brought into initial contact with formable material 124 on the substrate 102. The template 108 is bowed out by the template chuck 118 so that only a small portion of the template 108 is brought into contact with the formable material 124 at the target ICP. The bowing of the template is reduced as the template is brought closer to the substrate, until the template is flat, this is done to allow gas to escape during the contacting step S304 and to ensure that the formable material spreads in a controlled manner.

For full fields, the target ICP is at the center of the full field the mesa O_{i,m}. While the target ICP is a single point, the actual initial contact area is a larger area which may have an area of for example of 1 to 20 mm² which can be determined by around the time when interference fringes first start to show up in images obtained by the field camera 136. For partial fields, determining the target ICP is more complicated which depends on the shape and area of the partial field and the location of the partial field relative to the center of the substrate (Oₛ). For certain partial fields (e.g., those having an area that is 50% to less than 100% of the area of a full field) the target ICP may be at the same point as the full field or somewhere within the initial contact area. For other partial fields (e.g., those having an area that is 25%-50% of the area of a full field), the target ICP may be determined by calculating a geometric center (GC) or a centroid of the partial field. There are several methods that may be used for determining the GC. One method of estimating the GC is to use a method of intersecting meridians. Another method is to approximate the edge of the partial field using a function. The function may be defined in a piecewise manner and be continuous over the partial field. Integration may then be used to estimate a geometric center of the partial field. A third method of identifying the GC is to minimize distances from the GC to the farthest corners of the partial field.

The GC does not work as well for small partial fields. One method of determining a target ICP for small partial fields is described in US Patent Publication No. 2023-0014261 which is hereby incorporated by reference. As noted above, in an embodiment a partial field may be categorized as a small partial field 448 if it has an area that is less than a fractional area threshold for example 50% of the area of a full field or 35% of the area of a full field. For an alternative embodiment, the fractional area threshold may have a different value for example one of: 1%; 5%; 10%; 15%; 20%; 25%; 30%; 45%; 50% etc. In an embodiment, the target ICP is not the GC for small partial fields and the target ICP is coincident with the center of the mesa or could alternatively be the GC for partial fields that are not categorized as small partial fields.

As illustrated in FIGS. 4A-B different layouts of imprint fields results in different sizes and shapes of partial fields. The partial fields can have complex shapes with 1 to 4 four straight edges and 1 curved edge that meet at 2-5 vertexes for the example where the mesa is a quadrangle, and the substrate is a circle. When determining ICP control values for a partial field it is necessary to know the shape of the partial field. The traditional method of describing the shape of a partial field is to identify positions of all of the vertexes of the shape and the shape of lines connecting all these vertexes. Another method of describing a partial field is as the intersection of two shapes in which the size, shape, and relative positions of these shapes are listed. While this would provide a complete description of the partial field it is not necessary for purposes of determining ICP control values. A partial field shape description Fᵢ for a partial field i can be simplified to just two or three values. For example, a partial field shape description set Fᵢ may include: the area of the partial field shape relative to the area of a full field (F_{i,A}); and an azimuthal angle that represents the angle in the plane of the substrate of a center of the mesa relative to the middle of the substrate (F_{i,θ}) (Fᵢ={F_{i,A}, F_{i,θ}}) as illustrated in FIG. 4D. Also illustrated in FIG. 4D in the target ICP for the imprint field i (ICPᵢ={ICP_{i,r}, ICP_{i,θ}}). As illustrated in FIG. 4D the azimuthal coordinate of the imprint field i (ICP_{i,θ}) is different than the azimuthal coordinate of the partial field shape description (F_{i,θ}) although in some circumstances they may be the same.

### Method of Determining ICP Control Values

A method for determining ICP control values is disclosed in U.S. patent application Ser. No. 18/127,074, filed Mar. 28, 2023 (hereinafter, “the '074 application”), which is incorporated by reference herein it its entirety. In particular, the section of the '074 application titled “Method of Determining ICP control values” is the most relevant portion. The shaping process 300 includes a contacting step S304. As noted in the '074 application, the contacting step S304 includes receiving a set of contact control values Vᵢ for a partial field i from a processor 140. The set of contact control values Vᵢ may include: a template cavity pressure P_{T} applied to a portion of a template during initial contact of the template 108 with formable material 124 on a substrate 102 which causes the template 108 to be curved with radius of curvature of the template R_{T}; a set of substrate pressures (P_{Sa}, P_{Sb}, and P_{Sc}) applied to a portion of the substrate during initial contact of the template with formable material on the substrate which causes the substrate 102 in the partial field to be curved with a radius of curvature R_{S}; and a tilt (θ_{T}) of the template relative to the substrate during initial contact of the template with formable material on the substrate. The '074 application provides a flowchart of an ICP control value determination process for small partial fields 448. By implementing the method described in the '074 application, a set of calibration data Cⱼ associated with a specific imprint process j including the following data may be established: the tilt of the template tilt (θ_{j,T}); one or more substrate pressure control values (P_{j,Sa}, P_{j,Sb}, and P_{j,Sc}); template cavity pressure (P_{j,T}); area of the partial field (F_{j,A}); and azimuthal angle of the partial field (F_{j,θ}). As noted in the '074 application, the superset of calibration data C may include 10s; 100s or 1000s of sets of calibration Data Cⱼ.

As explained in the '074 application, the ICP control value determination process may include a control condition determination step in which the set of contact control values Vᵢ which allow the template 108 to initially contact the formable material 124 at the ICP_{i,D} are determined based on the partial field description Fᵢ, and the superset of calibration data [symbol] . The control condition determination step may output a set of contact control values Vᵢ which may then be used in a step S304 to imprint partial field i. The set of contact control values Vᵢ may include: a template cavity pressure P_{i,T}; a set of substrate pressures (P_{i,Sa}, P_{i,Sb}, and P_{i,Sc}); and a template tilt (θ_{i,T}).

### Initial Contact Control Values

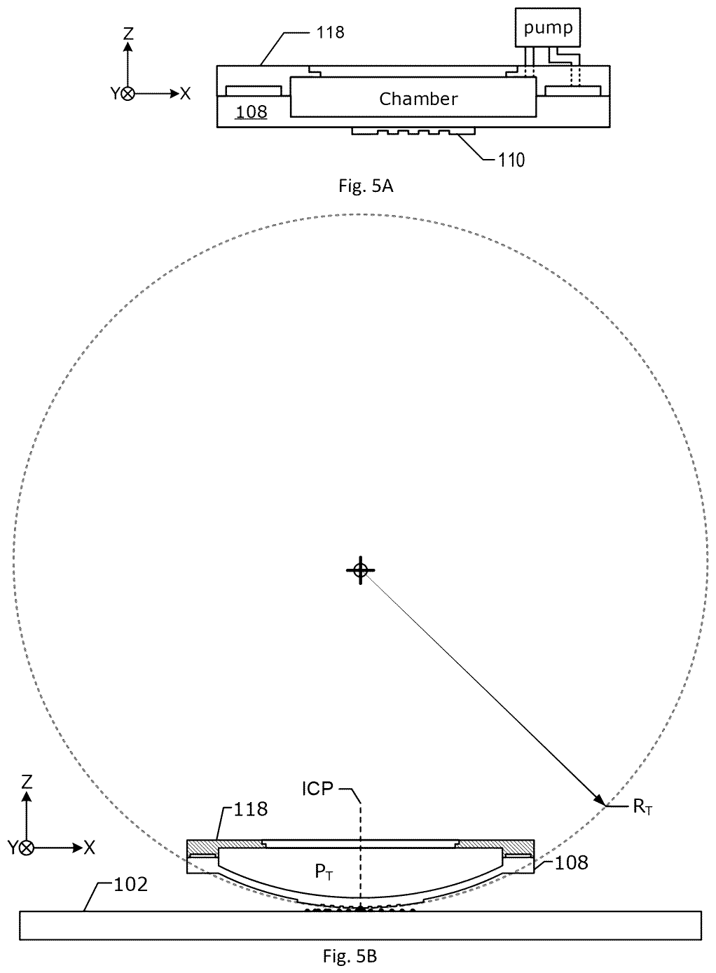

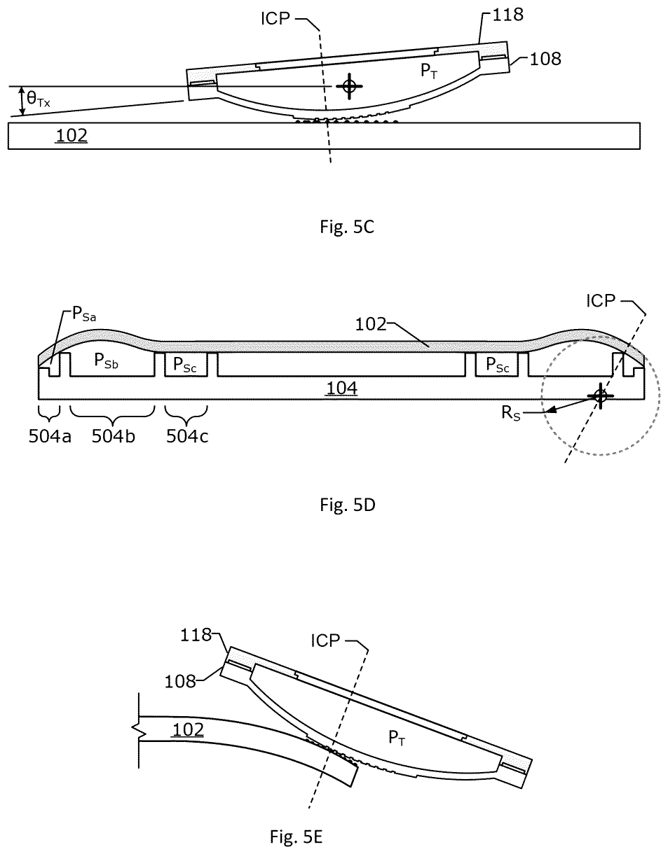

As discussed in the '074 application, the set of contact control values Vᵢ for an imprint field i may include a template back pressure (P_{i,T}) that is applied by the template chuck 118 to a back surface of the template which bows out the template 108 when imprinting partial field i. FIG. 5A is an illustration of a pump connected to an exemplary template chuck 108 for holding a template 108 details of which are described in US Patent Publication No. 2017/0165898 which is hereby incorporated by reference in its entirety. The template chuck 118 may include one or more vacuum portions which hold the template 108 and a chamber portion which can be used to bow out template 108 as illustrated in FIG. 5B when it is contacting a full field i. By increasing the pressure in the chamber above the ambient pressure of the shaping surface 112, the template 108 is bowed out causing the shaping surface 112 to have a curvature that may be approximated by a radius of curvature of the template (R_{T}) at the ICP. The radius of curvature of the template R_{T} is an approximate representative of a shape of the shaping surface 112 at the ICP. A polynomial (for example a fourth order polynomial) may also be used to approximate the shape of the shaping surface 112 in the region of the ICP at the time of initial contact. A finite element model or other simulation model may be used to determine a shape of the shaping surface under different control conditions.

The control conditions may include a tipping angle of the template (θ_{Tx} rotation of the template about the x-axis) and a tilting angle of the template (θ_{Ty} rotation of the template about the y-axis), which together are the template control angles (θ_{i,T}={θ_{i,Tx}, θ_{i,Ty}}) relative to the substrate as illustrated in FIG. 5C when imprinting a full field i. In an embodiment, θ_{Tx} may be a function G of θ_{Ty} and one or both components of the partial field description F of the imprint field i (θ_{i,Tx}=G(θ_{i,Ty}, Fᵢ)). In which case only one component of the template control angles needs to be known. The function G may be determined experimentally or through simulation such that certain conditions are maintained. The imprint head 120 may include a plurality of actuators that are used to position the template 108 relative to the substrate 102 these plurality of actuators can also be used to tilt the shaping surface 112 relative to the substrate 102. FIG. 5C shows the tilt of a reference surface (front surface of the template chuck) relative to the substrate 102 which is at the same angle as shaping surface 112 when it is not bowed out.

The control conditions may include a set of substrate chuck control values supplied to the substrate chuck 104. The substrate chuck 104 may deform a shape of the substrate 102. As illustrated in FIG. 5D, the substrate chuck 104 may be a zone chuck in which different zones (for example outer zone 504a, first inner zone 504b, second inner zone 504c, etc.) may be supplied with different amounts of positive or negative pressure which causes the substrate to be deformed by between 1-10 μm. The substrate chuck 104 has at least 2 zones but may have 3, 4, 5, 6, 7, 8, 9, 10, or more zones. For example, positive pressure may be supplied to the first inner zone 504b while negative pressures are supplied to the outer zone 504a and the second inner zone 504c. As with the template the shape of the substrate surface 130 may be approximately represented by a radius of curvature of the substrate (R_{S}) at the ICP. A polynomial (for example a fourth order polynomial) may also be used to approximate the shape of the shaping surface 112 in the region of the ICP at the time of initial contact. A finite element model or other simulation model may be used to determine a shape of the shaping surface under different control conditions.

The control conditions (a template cavity pressure P_{T} for controlling the radius of curvature of the template R_{T}; substrate pressures P_{Sa}, P_{Sb}, and P_{Sc} for controlling the radius of curvature of the substrate R_{S}; template tilts θ_{Tx} and θ_{Ty}; etc.) may be adjusted in combination or independently to control where the ICP is on the small partial field 448 as illustrated in FIG. 5E. The control conditions may include additional parameters which describe the shapes and orientations of the shaping surface 112 at ICP and the substrate surface 130 at ICP. The control parameters may include a plurality of control values and/or trajectories (pressures, currents, voltages, binary control signals, etc.) which are used to determine the shapes and orientations of the shaping surface 112 at ICP and the substrate surface 130 at ICP. The applicant has found that there are typically multiple different solutions to the selection of control conditions to achieve a specific ICP. The selection of which of these solutions is appropriate may depend upon the small partial field size, overlay constraints, alignment constraints, defectivity, process time, etc. This will also have an impact on which control conditions are adjusted as explained in the '074 application. As explained in the '074 application, the adjusting control conditions may be performed by adjusting template cavity pressure P_{T} while keeping the other control conditions at default setting(s) depending on the partial field area F_{i,A} and/or the azimuthal angle of the partial field (F_{i,θ}).

The amount of pressure that is supplied to the chamber depends on the desired radius of curvatures (R_{T}, R_{S}) at ICP and during the filling step S306 which may be determined based on reducing non-fill defects caused by gas not escaping during the filling step S306 for a given fill time. There are control limitations on the control parameters based on the mechanical characteristics of the template 108, the substrate 102, and the shaping system 100. These limitations prevent: the recessed surface 244 of the template from contacting the substrate surface 130 or an applique surrounding the substrate; and/or the shaping surface 112 from contacting the applique surrounding the substrate. In an alternative embodiment, the ICP is chosen within the ICP range based on limitations on the control parameters. These limitations may be determined experimentally, and/or using a finite element model or other simulation methods. For example, when both the template and substrate are flat the template angle can be calculated using trigonometry as described in equation (1) below. Once the shape of a bowed out shaping surface 112 and/or shape of bowed out substrate surface 130 are determined coordinate transformations may be used to determine the limitations. The relationship between θ_{i,Tx} and θ_{i,Ty} is also described in equation (1) below for an ideal value for θ_{i,Tx} and θ_{i,Ty}. The applicant has found that an ideal solution is not always effective and other values for θ_{i,Tx} and θ_{i,Ty} must be determined through simulation and experimentation.

$$\begin{matrix}{θ}_{max} = {tan}^{- 1} ( 2 \frac{{h}_{T}}{{w}_{T}} ) \\ {θ}_{i , Tx} = \{ \begin{matrix}{θ}_{max} sig ( cos ( {θ}_{i , m} ) ) , & cos ( {θ}_{i , m} ) > sin ( {θ}_{i , m} ) \\ \frac{{θ}_{i , Ty}}{tan ( {θ}_{i , m} ) sig ( sin ( {θ}_{i , m} ) )} , & cos ( {θ}_{i , m} ) \leq sin ( {θ}_{i , m} )\end{matrix} \\ {θ}_{i , Ty} = \{ \begin{matrix}{θ}_{i , Tx} tan ( {θ}_{i , m} ) sig ( sin ( {θ}_{i , m} ) ) , & cos ( {θ}_{i , m} ) > sin ( {θ}_{i , m} ) \\ {θ}_{max} sig ( sin ( {θ}_{i , m} ) ) , & cos ( {θ}_{i , m} ) \leq sin ( {θ}_{i , m} )\end{matrix}\end{matrix} \qquad ( 1 )$$

Generating the Superset of Calibration Data

[symbol]

As discussed in the '074 application each individual element of the superset of calibration data Cⱼ should include: control values Vⱼ; a partial field description Fⱼ; and the initial contact point ICPⱼ. Each set of calibration data Cⱼ may be determined via experimentation. In which a series of experiments are performed at a series of different partial fields as illustrated in FIG. 5F. For each partial field j with a specific partial field description (Fⱼ) multiple experiments are performed with different sets of control values Vⱼ that each produce a different ICPⱼ. Examples of such experiments are described in the '074 application.

Shaping Method with Switching Control Type

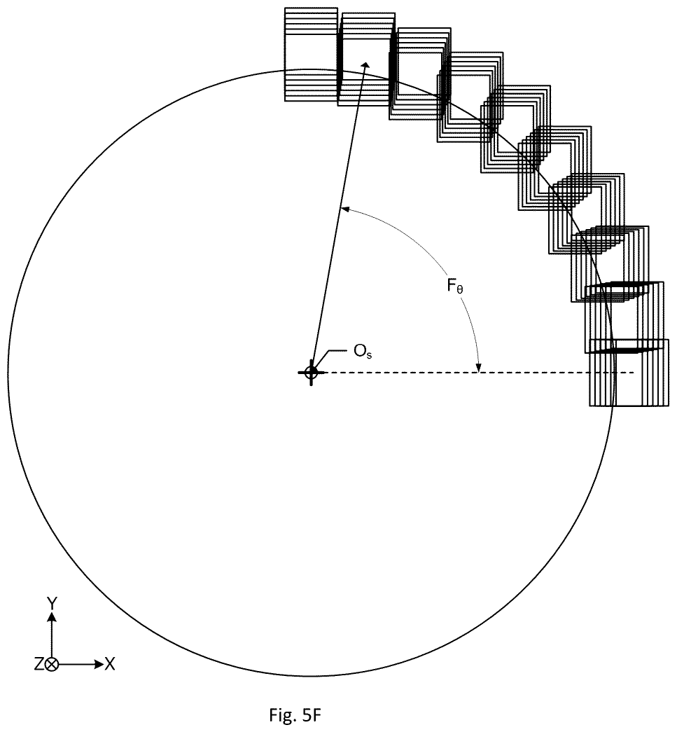

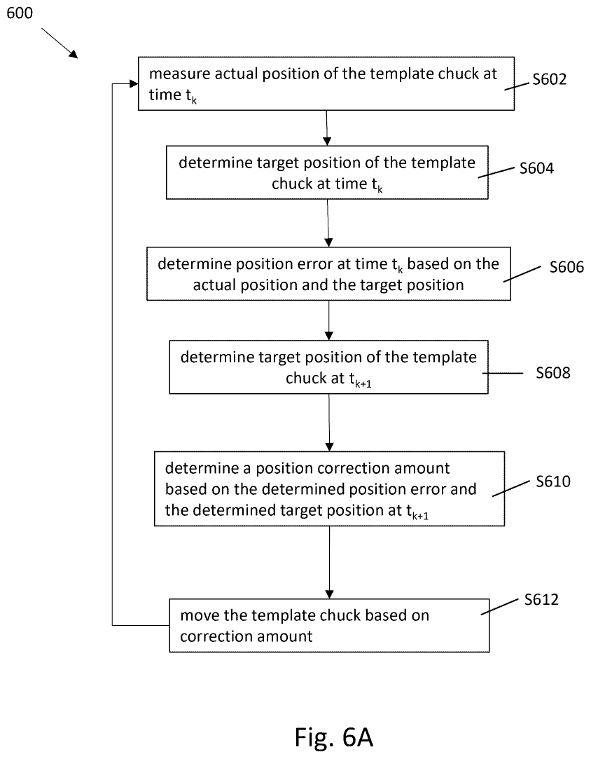

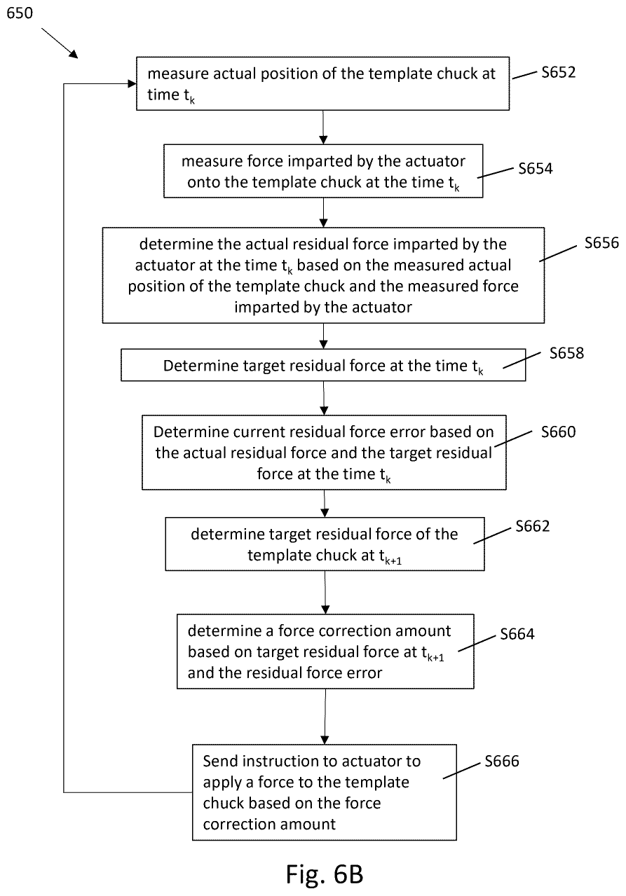

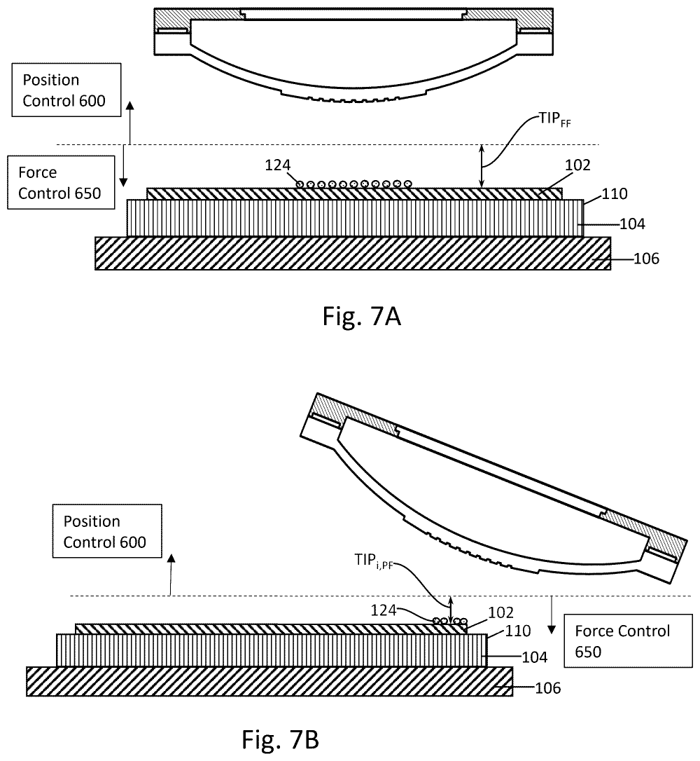

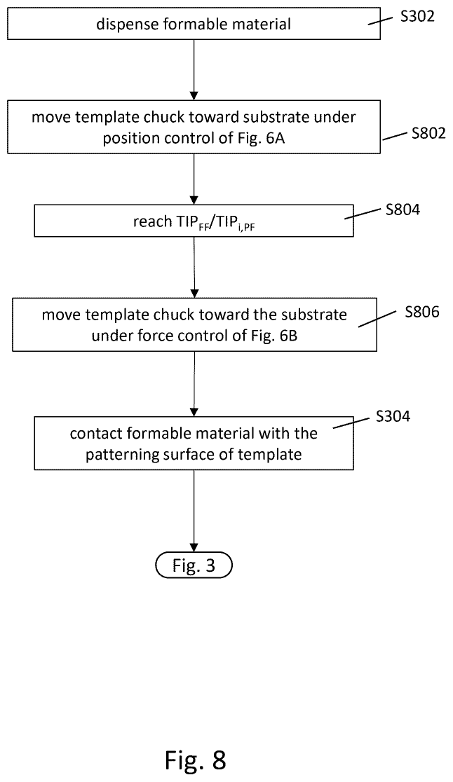

When imprinting a full field (and also when imprinting partial fields and small partial field discussed below), there are two control phases. The first control phase is referred herein as “position control.” The second control phase is referred herein as “force control.” Position control, as used herein, means that movement of the template chuck is controlled using a feedback loop that is based on measured position information of the template chuck and is not based on any information about force imparted onto the template chuck. Force control, as used herein, means that the movement of the template chuck is controlled using a feedback loop that is based on both measured position information of the temple chuck and on information about the estimated residual force imparted onto the template chuck. An example of a method of position control 600 is illustrated in the flowchart of FIG. 6A. An example of a method of force control 650 is illustrated in the flowchart of FIG. 6B. The position control method 600 is the same no matter what field is being printed (i.e., full, partial, small partial, etc.). Likewise, the force control method 650 is the same no matter what field is being printed (i.e., full, partial, small partial, etc.). Thus, the position control of FIG. 6A and the force control of FIG. 6B are applicable to any size field being imprinted.

The position control method 600 may begin with step S602 where the measured position of the template chuck is measured. The measured position of, for example, a top surface of the template chuck may be measured with three or more position encoders that measure the position of the template chuck relative to a resting plane. The actual position of the template chuck may include: a z-position along a z-axis; a rotation around an x-axis (θ_{i,Tx}); and a rotation around a y-axis (θ_{i,Ty}). The actual position of the template chuck may include three separate z-positions along three different z-axes. The actual position of the template chuck may be adjusted based on the imprint field i and measured height variation of the substrate chuck and/or substrate such that it is representative of a gap between the shaping surface 112 of a reference template swelled with a reference pressure and the substrate surface 130. The template chuck is an extended object and the position (including rotations) of the template chuck means the position of one or more reference points on the template chuck. If the reference point(s) are changed then calibration data will change accordingly. The reference point(s) may be based on the encoders used to measure the position of the template chuck. At the start of the method in step 602 it is presumed that the template chuck has already begun to move toward the substrate from a resting plane according to a predetermined position trajectory. The predetermined position trajectory is data indicating the desired position of the template chuck at a particular time during the shaping process. The predetermined position trajectory is the relative z position along the z-axis and may also include rotation around the x-axis (θ_{i,Tx}), and a rotation around the y-axis (θ_{i,Ty}) relative to a reference plane. The predetermined position trajectory may be a relative time series of data points, a smooth function of relative time, a piecewise smooth function of relative time. The predetermined position trajectory may be a differentiable function that is differentiable with respect to time over a time period in which the predetermined position trajectory is used. The predetermined position trajectory may be a twice differentiable function that is twice differentiable with respect to time over a time period in which the predetermined position trajectory is used. Relative time in the present context is time relative to an initial starting time that depends on when the template chuck leaves the resting plane. The resting plane may be a fixed location above the substrate chuck at which the template chuck rests in between imprinting when imprinting multiple fields on the substrate. The resting plane may be a neutral plane where the template chuck rests when no force is supplied by the actuators. The template chuck 118 may be connected to one or more springs and/or flexures that supply a resisting force that prevents the template from contacting the substrate unless the actuators supply a force. As the template chuck 118 begins to move toward the substrate 102 following the predetermined position trajectory, the position control method 600 feedback loop is implemented. Thus, the actual position of the template chuck 118 measured in step S602 is done at a particular time tₖ. The index k is a time index which represents a short time period in which measurements and actions are taken by the controller during the imprinting of a single field. In other words, each time the method of FIG. 6A is performed the actual position of the template chuck is measured for a particular time tₖ.

After measuring the actual position of the template chuck at particular time tₖ, the position control method 600 may proceed to step S604 where a target template chuck position is generated for the same time tₖ. The target template chuck position is the position that the template chuck should have been at according to the predetermined position trajectory at the time tₖ that the actual position was measured in step S602. In other words, if the template chuck had followed the predetermined position trajectory perfectly, the actual position measured in step S602 at time tₖ would be the same as indicated in the predetermined position trajectory at the time tₖ. However, this is typically not the case.

The position control method 600 may then proceed to step S606 where a position error of the template chuck at the time tₖ is determined. The position error is the difference between the target position of the template chuck at time tₖ determined in step S604 and the actual position of the template chuck at the same time tₖ measured in step S602. After the position error is determined, the method may proceed to step S608 where a target position of the template chuck is determined for the next time tₖ₊₁. As in step S604, the target position of the template at time tₖ₊₁ determined in step S608 is the position that the template chuck should be at according to the predetermined position trajectory at the time tₖ₊₁.

After determining the target position of the template chuck at the time tₖ₊₁ in step S608, the method may proceed to step S610 where a position correction amount is generated based on the position error determined in step S606 and the target position of the template chuck at time tₖ₊₁ determined in step S610. The position correction amount is how much the template chuck needs to be moved so that the position of the template chuck will more closely follow the predetermined position trajectory. Thus, once the correction amount is determined in step S610, the method may proceed to step S612 where the template chuck 118 is moved based on the correction amount. This is achieved by sending an instruction to the actuator acting upon the template chuck to move the template chuck toward the substrate. The instruction may be a specific desired position at the time tₖ₊₁ for each of the actuators or a specific control effort that each of the actuators will supply. The instructions to the actuator may be generated using for example a PID type control system, a state-space control system, or some other control system that takes current and past information into account. The method then proceeds back to step S602 to repeat the method so that any position error is continuously accounted for while the template chuck approaches the substrate. If position error is not continuously accounted for, the actual position of the template chuck 118 will not follow the predetermined position trajectory.

The force control method 650 may begin with step 652 where the actual position of the template chuck is measured in the same manner as step S602. At the start of the method in step 652 the template chuck has already moved toward the substrate following the position control method 600 and is now moving following a predetermined force trajectory. The timing of switching between the two control schemes is discussed below. The predetermined force trajectory is data indicating what the desired residual force imparted onto the template chuck by the one or more actuators should be at a particular relative time during an imprinting process. The residual force is the net force of the forces acted upon the template chuck by the one or more actuators and any counteracting forces imparted by one or more springs and/or flexures. The predetermined force trajectory is the residual force that has been experimentally determined to have good filing performance of the formable material 124 during the contacting period T_{contact} and the filling period T_{f}. As soon as the template chuck begins to move toward the substrate to follow the predetermined force trajectory, the force control method 650 feedback loop is implemented. Thus, the actual position of the template chuck measured in step S652 is performed at a particular time tₖ. In other words, each time the method of FIG. 6B is performed, the actual position of the template chuck is measured for a particular time tₖ.

After measuring the actual position of the template chuck at particular time tₖ (step S652), the force control method 600 may proceed to step S654 where the force being imparted by the actuator onto the template chuck is measured at the same time tₖ. The actual force being imparted by the actuator may be measured by for example by measuring the control current, control voltage, output of a force sensor, or the instructed force supplied by the supplied by the controller to the one or more actuators. After measuring the force imparted to by the actuator in step S654, the method may proceed to step S656 where the estimated residual force imparted by the actuator at the time tₖ is determined. The estimated residual force is the net force applied onto the template chuck. The estimated residual force is determined from the measured actual positions of the template at the time tₖ (S652) and the measured force imparted on the template chuck 118 at time tₖ (S654). The estimated residual force depends on the position of the template chuck determined in step S652 because as the template chuck 118 moves closer the substrate 102 the spring forces and flexure forces varies with the position of the template chuck relative to the bridge. The estimated residual force may be measured based on previously gathered calibration data and the sensed position. In an embodiment, there may be multiple residual forces (one for each actuator). The multiple residual forces may be generated using a MIMO (multiple input multiple output) calibration process. Thus, knowing the position of the template chuck correlates to the force imparted by the one or more flexures and springs and one can determine the residual force.

After determining the estimated residual force (S656), the method proceeds to step S658 where a target residual force is determined for the same time tₖ. The target residual force is the net force that should have been imparted onto the template chuck 118 according to the predetermined force trajectory at the time tₖ that the actual position was measured in step S652. In other words, if the template chuck 118 had followed the predetermined force trajectory ideally, the estimated residual force determined in step S656 at time tₖ would be the same as indicated in the predetermined force trajectory at the time tₖ. However, because of noise in the environment and positioning system and the desire to have sub-Newton force control during the contacting period T_{contact} and the filling period T_{f} this is typically not the case.

The force control method 650 may then proceed to step S660 where a residual force error on the template chuck at the time tₖ is determined. The residual force error is the difference between the target residual force on the template chuck at time tₖ determined in step S658 and the estimated residual force on the template chuck at the same time tₖ measured in step S656. After the residual force error is determined, the method may proceed to step S662 where a target residual force on the template chuck is determined for the next moment in time tₖ₊₁. The target residual force for the next moment in time tₖ₊₁ is obtained from the predetermined force trajectory. As in step S658, the target residual force on the template at time tₖ₊₁ determined in step S662 is the residual force that should be applied to the template chuck by the actuator in order to comply with the predetermined force trajectory at the time tₖ₊₁.

After determining the target residual force on the template chuck at the time tₖ₊₁ (S662), the method may proceed to step S664 where a force correction amount is determined based on the residual force error determined in step S660 and the target residual force at time tₖ₊₁ determined in step S662. The force correction amount is how much force the actuator needs to apply to the template chuck so that template chuck will more closely follow the predetermined force trajectory. The force correction amount may be a specific desired force to be supplied at the time tₖ₊₁ for each of the actuators or a specific control effort that each of the actuators will supply. The instructions to the actuator may be generated using for example a PID type control system, a state-space control system, or some other control system that takes current and past information into account. Thus, once the force correction amount is determined in step S664, the method may proceed to step S666 where an instruction is sent to the actuator to apply a force onto the template chuck based on the correction amount from step S664. Upon receiving the instruction, the actuator will provide the force from step S666 which will move the template chuck toward the substrate. The method then proceeds back to step S652 and the method is repeated so that any force error is continuously accounted for while the template chuck approaches the substrate. If residual force error is not continuously accounted for, the estimated residual force of the template chuck will not follow the predetermined residual force trajectory.

As noted above, in the shaping/imprinting process, the template chuck movement is initially controlled according to the position control method 600 and then, at a predetermined moment in the shaping/imprinting process, control of the template movement switches to the force control method 650. More particularly, there is an ideal distance from the substrate where switching between the two types of control methods provides optimal shaping/imprinting results. The location where ideal switching occurs is referred herein as the target imprint plane (TIP). The TIP is a virtual plane located at a distance in the Z direction from the substrate. The TIP is parallel to an average plane of the substrate surface 130 of the imprint field to be imprinted, when the substrate is held flat and does not change even if the template is tilted or otherwise non-parallel and the substrate is deformed by differential pressures applied by different zone of the substrate chuck. The target imprint plane can be experimentally determined. To determine the TIP, a series of testing imprints are performed. In each test imprint, a different location of the potential TIP (i.e., the Z dimension location where switching between position control and force control occurs) is implemented, with all other factors being kept the same. That is, the identical imprinting process is performed with the only difference being the location of the potential TIP. The results of the imprinting are examined to determine which potential TIP location provides satisfactory performance. The satisfactory performance may be determined by examining which has the best filling performance, minimal defects, uniform RLT, and throughput within an acceptable error. The tested TIP that provided the satisfactory performance is determined to be the actual TIP to be used. In the case of full fields, all future full field imprints of the same pattern, same imprinting process, and using the same imprinting system will have the same TIP. That is, for a full field, once the TIP is determined it can be applied to all full field imprinting using the same imprinting system for the same pattern and for the same process. FIG. 7A shows a schematic sectional view of a swelled template as it approaches the TIP for a full field imprinting (TIP_{FF} being the TIP for a full field).

The reference point for determining when a template chuck has reached the TIP is for example 5-10 μm between the shaping surface 112 and the substrate surface 130. The reference point for determining when a template chuck has reached the TIP for a full field, a partial field, or a small partial field may be the average z position as measured by the three position encoders used to measure the position of the template adjusted to take into account variation in height of the substrate chuck. The reference point may also be a specific point on the template or the template chuck. The reference point may be the center of mass of the template chuck. The reference point may be the center of mass of the template chuck, and portions of shaping head that that move with the template chuck.

However, the TIP for a full field is not applicable to a partial field and small partial fields. This is primarily because for partial fields, and more particularly for small partial fields, the swelling of the template during imprinting is different for each unique partial field. Furthermore, when imprinting partial fields and small partial fields at the edge of the substrate, the substrate is modulated to curve the substrate (see FIGS. 5D-E). Thus, if the TIP for a full field is used when imprinting partial field or small partial fields, the imprinting performance is often not satisfactory.

FIG. 7B shows a schematic sectional view of a swelled template at is approaches the TIP for partial field or small partial field imprinting (TIP_{PF} being the TIP for a partial field or small partial field).

While it is possible to determine the TIP for each unique partial field and small partial field, it is unduly burdensome and requires multiple experiments. Rather than experimentally determining the TIP for every partial field and small partial field, the TIP can be estimated based on the already determined TIP for a full field. The following formula (1) can be used to estimate the TIP for partial fields or small partial fields based on the known TIP for full fields.

$$T I {P}_{i , PF} = T I {P}_{FF} Sw * ( {P}_{T , FF} - {P}_{i , T , PF} ) \qquad ( 1 )$$

In formula (1):
TIP_{FF} is the TIP for a full field, which is a first distance from the substrate;
TIP_{i,PF} is the TIP for a particular partial field or small partial field i, which is a second distance from the substrate;
Sw is a swell ratio of the template;
P_{T,FF} is the back pressure control value for a full field;
P_{i,T,PF} is the back pressure control value for the particular partial field or small partial field i.

As discussed above, TIP_{FF} is a known value (distance from the substrate) determined through prior experimentation and is constant for all full fields once determined in a particular imprinting system.

Sw is a property of the particular template and is determined experimentally. For a particular template, the template is loaded on the imprint head and different back pressures are applied to the template so that it bends toward the substrate. The distance between the maximum extended point of the template (generally at the center) and the substrate (or “swell”) is measured for each different applied backpressure. Enough measurements are taken so that a trendline can be fitted to the data, which is generally a linear fit. The slope of the fitted line is the swell ratio Sw of the particular template. The units for Sw is distance/pressure, e.g., μm/kPa.

P_{T,FF} is determined as discussed above with respect to control value P_{T}, and described in detail in the '074 application. “FF” refers specifically to a full field, but is otherwise the same control value as P_{T}.

P_{i,T,PF} is determined as discussed above with respect to control value P_{i,T}, and described in detail in the '074 application. “PF” refers specifically to a partial field or a small partial field, but is otherwise the same control value as P_{i,T}.

Using the above formula (1), with TIP_{FF} being known, Sw being known, P_{T,FF} being known, and P_{i,T,PF} being known, it is possible to determine TIP_{i,PF} for each partial field or small partial field i. Notably, by using this formula, TIP_{i,PF} is determined without the need to experimentally determine TIP_{i,PF} for each partial field or small partial field i.

In another example aspect, the formula (1) may be modified to account for template tilt control parameters (θ_{i,T}={θ_{i,Tx}, θ_{i,Ty}}, FIG. 5C, discussed above) and substrate pressures control parameters (P_{i,Sa}, P_{i,Sb}, and P_{i,Sc}, FIG. 5D, discussed above). That is, the tilt of the template and the substrate pressures may also impact the desired TIP_{i,PF}. Thus, the formula (1) can be modified such that TIP_{i,PF} is additionally based on template tilt and substrate pressures or any other change to the template or substrate surface to cause a topographical change around the partial field.

Returning to the shaping method 300, FIG. 8 illustrates additional steps of the method 300 spanning steps S302 to S306. As shown in FIG. 8, after the formable material has been dispensed in step S302, and prior to the contact step S304, the method includes step S802 where the template chuck is moved toward substrate under position control of FIG. 6A. That is, prior to contact step S304, the template chuck movement follows the position control method 600.

Next, as shown in FIG. 8, the template chuck continues to move toward the substrate under position control method 600 until the TIP is reached. In the case of a full field being imprinted, the TIP is notated as TIP_{FF}, which as discussed above is the same location for every full field. As noted above, TIP_{FF} is illustrated in FIG. 7A and is predetermined distance from the substrate based on experimentation. In the case of a partial field or small partial field being imprinted, the TIP is notated as TIP_{i,PF}, which as discussed above is the TIP determined for a particular partial field or small partial field. As noted above, TIP_{i,PF} is illustrated in FIG. 7B and is predetermined distance from the substrate using formula (1) and does not need to be determined from experimentation. The moment in the overall imprinting process that the TIP_{FF}/TIP_{i,PF} is reached may be based on timing or based on location information of the template chuck. That is, in the case of teaching the TIP_{FF}/TIP_{i,PF} being based on timing, the controller may be provided with instructions that at a certain predetermined time in the imprinting process, the template chuck will have reached the predetermined TIP_{FF}/TIP_{i,PF}. In the case of location information, the predetermined TIP_{FF}/TIP_{i,PF} will have been reached when position sensor information informs the controller that the template chuck is at the proper location.

After reaching the TIP_{FF}/TIP_{i,PF} the method may proceed to step S806 where the movement of the template chuck switches from the position control method 600 of FIG. 6A to the force control method 650 of FIG. 6B. Preferably, the switch occurs simultaneously or contemporaneously with the template chuck reaching the TIP_{FF}/TIP_{i,PF}. More preferably, the switch occurs simultaneously, i.e., such that step S804 and step S806 occurs at the same instant. In another aspect, the switch may occur contemporaneously, i.e., step S806 occurs within several milliseconds of step S804.

After switching to force control in step S806, forces are applied to the template chuck such that the template chuck continues to move toward the substrate under force control until the contact with the formable material is reached (S304). The force control continues until the contact step S304 is complete, i.e., at the end of T_{contact}. Towards the end of the contact period, force control continues to apply force, although the template chuck may no longer be moving. After completing the contact step S304, the method continues with steps in FIG. 3. That is, the method proceeds to steps S306, S308, etc., according to the method 300 of FIG. 3. Thus, as shown in FIGS. 3 and 8, the additional steps S804 to S808 exist within the overall method 300.

All fields can be imprinted using the same method 300 including the additional steps of FIG. 8. That is, the same method 300 is applicable to full fields, partial fields, and small partial fields. The difference is that for all full fields the same TIP_{FF} is used and the same control values are used, while for each unique partial field and small partial field a unique TIP_{i,PF} and unique control values are used that are unique to the particular partial/small partial field.

When performing the method 300, the control values discussed in the '074 application are implemented in the similar manner as discussed in the '693 patent, except that the moment that TIP_{FF}/TIP_{i,PF} is reached (t_{TIP}) just before T_{contact} begins. That is, the moment t_{TIP} is reached is just before initial contact time (t_{IC}), and the moment t_{TIP} is when the control switches from the position control method 600 to the force control method 650.

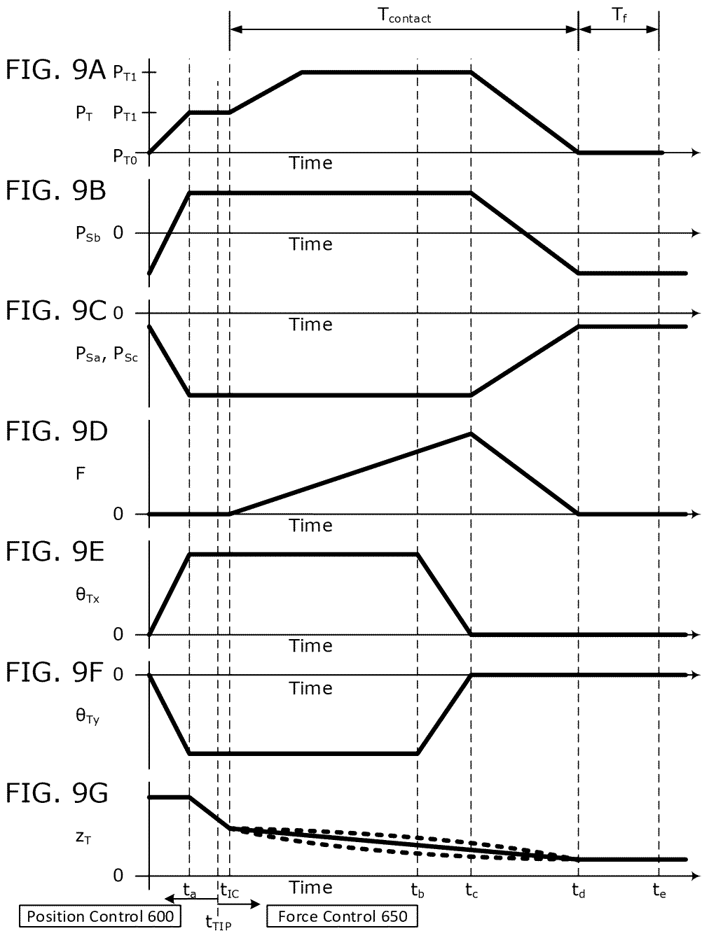

FIGS. 9A-G are timing diagrams illustrating how control conditions may vary over time before and after the initial contact time (t_{IC}) in an exemplary embodiment of imprinting partial fields and small partial fields. FIGS. 9A-G also show the at the time that TIP is reached (t_{TIP}) relative to the initial contact time (t_{IC}). FIG. 9A is a timing diagram illustrating how the template back pressure (P_{T}) is adjusted to an initial template bowing pressure (P_{T1}) prior to the initial contact time (t_{IC}) and then adjusted to a gas release template bowing pressure (P_{T2}) after the initial contact time (t_{IC}). The template back pressure (P_{T}) is then adjusted until the template is flat relative to the substrate.

FIGS. 9B-C are timing diagrams illustrating how the substrate back pressures (P_{Sa}, P_{Sb}, and P_{Se}) are adjusted to bow out the substrate prior to the initial contact time (t_{IC}) and then the pressure is adjusted prior to curing step S308 so that the substrate and the template are parallel to each other during the curing step S308.

FIG. 9D is a timing diagram illustrating how the contact force that the template 108 applies to the formable material 124 may be adjusted during the shaping process 300. The contact force may increase after the initial contact time (t_{IC}) and then be reduced to a final imprint force prior to start of the curing step S308.

FIGS. 9E-F are timing diagrams illustrating how the template 108 and the substrate 102 are oriented relative to each other. The template control angles (θ_{T}) may be increased prior to the initial contact time (t_{IC}) and are then reduced until the template and substrate are parallel with each other during the curing step S308.

FIG. 9G is a timing diagram illustrating how the template chuck position (z_{T}) is adjusted during a part of the shaping process 300. The distance between the template chuck and the substrate is reduced until the bowed out template 108 comes into contact with the formable material 124 at the initial contact time (t_{IC}). The position is then adjusted as the template, and substrate, become unbowed and parallel to each other until there is a small residual layer thickness of formable material between the shaping surface 112 and the substrate surface 130 during the curing step S308.

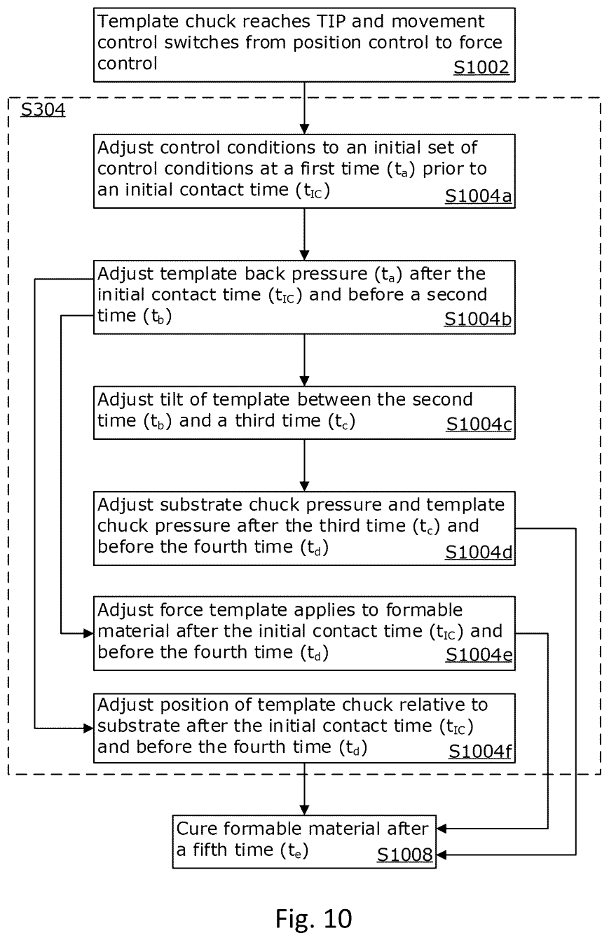

FIG. 10 is a flowchart illustrating more detailed steps performed during the contacting step S304 for partial fields and small partial fields in an exemplary embodiment. As noted above, prior to step S304, the template chuck moves according to the position control method 600 of FIG. 6 and switches to the force control method 650 upon reading the TIP (step S1002). The contacting step S304 may include an initial control conditions setting step S1004a in which the control conditions are adjusted to an initial set of control conditions at a first time (tₐ) prior to an initial contact time (t_{IC}). The initial set of control conditions may include: a template back pressure (P_{T}) to an ICP template back pressure; the tip and tilt of the template (θ_{T}); first inner ring substrate pressure (P_{Sb}); outer ring substrate pressure (P_{Sa}); second inner ring substrate pressure (P_{Sc}); the template chuck position (z_{T}); etc. The tilts, the template chuck position (z_{T}), and pressures should be adjusted to the values which controls the ICP at the initial contact time (t_{IC}) as discussed in the '693 patent.

After the first time (tₐ) the template chuck position is adjusted until the shaping surface 112 is brought into contact with the formable material 124 at the ICP at the initial contact time (t_{IC}). After the initial contact time (t_{IC}) and before a second time (t_{b}), the template chuck 118 may adjust the template back pressure (P_{T}) from an ICP template back pressure to a gas escape template back pressure in a back pressure adjustment step S1004b. The gas escape template back pressure may be greater than the ICP template back pressure. The ICP template back pressure is chosen to ensure that initial contact happens correctly while the gas escape template back pressure is chosen to ensure that gas can escape as droplets of formable material spread underneath template as more of the template is brought into contact with the formable material.

Between the second time (t_{b}) and a third time (t_{c}), the tip and tilt of template is adjusted in a tilt adjustment step S1004c until the template chuck is substantially parallel to the substrate chuck. After the tilt is adjusted, in a pressure adjustment step S1004d the substrate chuck pressure and template chuck pressure are adjusted after the third time (t_{c}) and before the fourth time (t_{d}) until both the template and the substrate are no longer bowed out. In an alternative embodiment, the pressure adjustment step S1004d is performed at the same time as the tilt adjustment step S1004c. In another alternative embodiment, the pressure adjustment step S1004d is performed before the tilt adjustment step S1004c.

At the initial contact time (t_{IC}) and before the fourth time (tₐ), during a force adjustment step S1004e, the force that the shaping surface 112 applies to the formable material is adjusted until a final force is reached that will be applied during the curing step S308 as illustrated in FIG. 9D. After the initial contact time (t_{IC}) and before the fourth time (t_{d}), during a template position adjustment step S1004f the position of the template chuck (z_{T}) is adjusted relative to the substrate chuck until there is a set residual layer thickness of formable material between the shaping surface and the substrate surface.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. An imprinting method comprising:
moving a template having a shaping surface towards a substrate based on first predetermined position information;
upon reaching a first predetermined distance from the substrate, switching from moving the template based on the first predetermined position information to moving the template based on first predetermined force information;
contacting the shaping surface with formable material on the substrate such that the total surface area of the shaping surface overlaps the substrate,
moving the template towards a substrate based on second predetermined position information;
upon reaching a second predetermined distance from the substrate, switching from moving the template based on the second predetermined position information to moving the template based on second predetermined force information;
contacting, with the shaping surface, the formable material on the substrate, wherein the shaping surface overlaps an edge of the substrate,
wherein the second predetermined distance is equal to the first predetermined distance that is adjusted based on at least one control parameter associated with contacting the formable material with the shaping surface when the shaping surface overlaps the edge of the substrate.

2. The method of claim 1, wherein the at least one control parameter is a value selected from the group consisting of a backpressure control value, a template tilt control value, and a substrate pressure control value.

3. The method of claim 1, wherein the at least one control parameter is a backpressure control value.

4. The method of claim 3, wherein the backpressure control value is a predetermined backpressure applied to the template at the time the template initially contacts the formable material.

5. The method of claim 3, further comprising increasing a backpressure applied to the template prior to the template reaching the second predetermined distance from the substrate.

6. The method of claim 1, wherein the first predetermined distance is adjusted based on a swell ratio of the template.

7. The method of claim 1, wherein the first predetermined distance is adjusted based on at least one control parameter associated with contacting the formable material with the shaping surface when the total surface area of the shaping surface overlaps the substrate.

8. The method of claim 7, wherein the at least one control parameter associated with contacting the formable material with the shaping surface when the total surface area of the shaping surface overlaps the substrate is a backpressure control value.

9. The method of claim 7,
wherein the at least one control parameter associated with contacting the formable material with the shaping surface when the shaping surface overlaps the edge of the substrate is a backpressure control value, and
wherein the first predetermined distance is adjusted based on a difference between the backpressure control value associated with contacting the formable material with the shaping surface when the total surface area of the shaping surface overlaps the substrate and the backpressure control value associated with contacting the formable material with the shaping surface when the shaping surface overlaps the edge of the substrate and.

10. The method of claim 9,
wherein the first predetermined distance is adjusted based on a swell factor of the template multiplied by the difference between the backpressure control value associated with contacting the formable material with the shaping surface when the total surface area of the shaping surface overlaps the substrate and the backpressure control value associated with contacting the formable material with the shaping surface when the shaping surface overlaps the edge of the substrate.

11. The method of claim 1,
wherein the second predetermined distance satisfies the following formula (1):
$$T I {P}_{PF} = T I {P}_{FF} Sw * ( {P}_{T , FF} - {P}_{T , PF} ) \qquad ( 1 )$$
wherein TIP_{PF} is the second predetermined distance,
wherein TIP_{FF} is the first predetermined distance,
wherein Sw is a swell value of the template,
wherein P_{T,PF} is a backpressure control value associated with contacting the formable material with the shaping surface when the shaping surface overlaps the edge of the substrate, and
wherein P_{T,FF} is a backpressure control value associated with contacting the formable material with the shaping surface when the total surface area of the shaping surface overlaps the substrate.

12. The method of claim 1, wherein in the case that the shaping surface overlaps an edge of the substrate, 85% or less of the shaping surface overlaps the substrate.

13. The method of claim 1, wherein in the case that the shaping surface overlaps an edge of the substrate, 50% or less of the shaping surface overlaps the substrate.

14. The method of claim 1, wherein in the case that the shaping surface overlaps an edge of the substrate, 35% or less of the shaping surface overlaps the substrate.

15. The method of claim 1, further comprising determining that the template has reached the second predetermined distance based on a predetermined time.

16. The method of claim 1, further comprising determining that the template has reached the second predetermined distance by measuring a position of a template chuck holding the template.

17. The method of claim 1, wherein second predetermined position information is position trajectory information and the second predetermined force information is force trajectory information.

18. A method of manufacturing an article, from a substrate on which a formable material was imprinted according to the method of claim 1, further comprising:
exposing the formable material under the template to actinic radiation;
processing the substrate; and
forming the article from the processed substrate.

19. An imprinting method comprising:
moving a template with a shaping surface towards a substrate based on predetermined position information;
upon reaching a predetermined distance from the substrate, switching from moving the template based on the predetermined position information to moving the template based on predetermined force information;
contacting, with the shaping surface, formable material on the substrate, wherein the shaping surface overlaps an edge of the substrate,
wherein the predetermined distance is equal to a reference distance from the substrate that is adjusted based on at least one control parameter associated with contacting the shaping surface with the partial overlap amount, and
wherein the reference distance is a distance from the substrate where, in a reference imprinting in which the total surface area of the shaping surface overlaps the substrate, movement of the template switches from being moved based on reference position information to being moved based on reference force information.

20. A imprinting system comprising:
one or more memory; and
one or more processors configured to:
move a template having a shaping surface towards a substrate based on first predetermined position information;
upon reaching a first predetermined distance from the substrate, switch from moving the template based on the first predetermined position information to moving the template based on first predetermined force information;
move the shaping surface with formable material on the substrate such that the total surface area of the shaping surface overlaps the substrate,
move the template towards a substrate based on second predetermined position information;
upon reaching a second predetermined distance from the substrate, switch from moving the template based on the second predetermined position information to moving the template based on second predetermined force information;
contact, with the shaping surface, the formable material on the substrate, wherein the shaping surface overlaps an edge of the substrate,
wherein the second predetermined distance is equal to the first predetermined distance that is adjusted based on at least one control parameter associated with contacting the formable material with the shaping surface when the shaping surface overlaps the edge of the substrate.
